(19) United States
(12) Patent Application Publication
(10) Pub. No.: US 2005/0029226 A1
(43) Pub. Date: Feb. 10, 2005

(54) Plasma etching using dibromomethane addition

(75) Inventor: Lyle T. Leverich, Saratoga, CA (US)

Correspondence Address: Marger Johnson & McCollom, P.C., 1030 S.W. Morrison Street, Portland, OR, 97205, US

(73) Assignee: Advanced Power Technology, Inc., Bend, OR (US)

(21) Appl. No.: 10/909,953

(22) Filed: Jul. 30, 2004

Related U.S. Application Data
(60) Provisional application No. 60/493,686, filed on Aug. 7, 2003.

(51) Int. Cl. G01R 31/00

(52) U.S. Cl. 216/59

(57) ABSTRACT

The disclosure relates to a plasma etch chemistry which allows a near perfectly anisotropic etch of silicon. A Cl-based plasma etch such as SiCl₄+Cl₂ has CH₂Br₂ added thereto, readily allowing the anisotropic etching of silicon. The silicon surface facing the discharge is subjected to ion bombardment, allowing the volatilization (etching) of silicon as a Si—Cl—Br compound. The Br which adsorbs on the sidewalls of the etched silicon passivates them from the etching. This new plasma etch chemistry yields a very smooth etched surface, and the etch rate is relatively insensitive to the electrical conductivity of the silicon. The use of dibromomethane is an improvement over the prior art which typically used HBr; a poisonous and ozone depleting gas. Dibromomethane is a relatively safe gas and not ozone depleting, yet giving substantially similar results in plasma etching of silicon, silicon nitride, and other materials.

### CROSS REFERENCE TO RELATED APPLICATIONS

This application claims priority from U.S. Provisional Application No. 60/493,686, filed on Aug. 7, 2003, which is incorporated herein by reference.

### BACKGROUND OF THE INVENTION

1. Field of the Invention

This invention relates to the field of semiconductor devices and, more particularly, to anisotropic plasma etching of silicon.

2. Description of the Prior Art

Plasma etch processes currently used to etch materials for semiconductor device fabrication consist of an electrical discharge of halogen bearing gases. Halogens typically encountered in these processes are fluorine, chlorine and bromine. The process begins with application of a masking material, such as photoresist, to protect the desired geometry of the device from the etch process. The device in process is then placed in a plasma reactor and etched. The subsequent steps are determined by the type of device being fabricated. This process is especially valuable for the definition of small geometry on the order of less than one to five microns. For definition of geometry of less than one micron, it is essential that the etching proceeds only in the vertical direction. The fragile nature of the small geometry structures cannot have a reasonable degree of reliability if any significant amount of undercutting takes place during the process.

A very common silicon etch process is based on fluorine. When mixtures such as CF₄—O₂ are dissociated in an electrical discharge, fluorine atoms are liberated, and volatilize the silicon as SiF₄. Such processes are isotropic; they etch in all directions at the same rate. Anisotropic, or vertical, etches in silicon are not observed when fluorine is the sole etchant.

In U.S. Pat. No. 4,226,665, Mogab describes etch chemistries which yield vertical etches. For vertical etching of silicon a chemistry such as C₂F₆—Cl₂ is indicated. The C₂F₆ serves as a source of “recombinants”, such as CF₃. The recombinants suppress etching in the horizontal direction by recombining with Cl atoms, which have been adsorbed on the etched walls. Etching can proceed in the vertical direction because ion bombardment from the plasma suppresses the recombination mechanism.

Chemistries based on chlorine have been considered to be necessary for vertical etching of silicon, and discharges of pure Cl₂ have been found useful for this purpose. However, some silicon materials, such as highly doped polysilicon, still experience some undercutting if etch conditions are not closely controlled.

Furthermore, the use of chlorocarbons as the Cl source for etching polysilicon is not desirable. Selectivity to the underlying SiO₂ layer is a constant problem because the C is a good reducer of SiO₂, combining with the O to form CO and CO₂. A practical limit on the selectivity of doped polysilicon to SiO₂ appears to be roughly 20:1.

In U.S. Pat. No. 4,490,209, Hartman describes the addition of HBr to etch polysilicon. HBr is a poisonous and ozone depleting gas.

In addition, in the production of most MOS integrated circuits, the polysilicon to be etched overlays a thin silicon dioxide layer. It is essential that the etching of the polysilicon does not continue very far into this thin layer. The preferred embodiment of this invention includes a reasonable selectivity to silicon dioxide.

Accordingly, there is a need to develop a plasma etch chemistry which provides a safe and accurate anisotropic etch of silicon and selectivity to silicon dioxide without the prior art problems such as undercutting.

### SUMMARY OF THE INVENTION

In one embodiment, there is provided a method for selectively etching a layer of a silicon-bearing material in producing a semiconductor device. A patterned masking material is provided over the silicon-bearing material to expose portions of the silicon-bearing material to be etched. A gaseous mixture is passed over the layer. The gaseous mixture comprises dibromomethane. Preferably, the method further includes creating a plasma discharge in the gaseous mixture adjacent the layer of silicon-bearing material.

In one aspect of the present invention, there is provided a plasma etch chemistry which has been shown to be capable of nearly perfectly vertical etching of silicon or materials having a significant silicon content, yet it does not present the problems noted above by the prior art. In a preferred embodiment, dibromomethane is added thereto, and anisotropic etching is provided. This is accomplished by the adsorption of a Si—Br compound on the sidewalls of the etch cavity, while the ion bombardment on the flat surface inhibits the formation of the compound in that area. The silicon may be etched as Si—Cl—Br compound.

Dibromomethane is a relatively safe gas and not ozone depleting, yet giving substantially similar results in plasma etching of silicon, silicon nitride, and other materials, and therefore is an improvement over the prior art.

The etch process includes selectively etching a layer of silicon or silicon compound. The material is first masked then placed in a plasma reactor, where the plasma chemistry consists of dibromomethane and chlorine gaseous compounds and/or fluorine gaseous compounds.

### BRIEF DESCRIPTION OF THE DRAWING

FIG. 1 is a cross-sectional view showing the operation by the etch process of one embodiment of the present invention.

### DETAILED DESCRIPTION OF THE INVENTION

The present invention teaches that a highly anisotropic etch can be achieved by the addition of dibromomethane to the silicon etching chemistry. Ion bombardment overcomes the resistance to etching on flat surfaces, but lateral etching can be suppressed by the formation of a Si—Br compound on the sidwalls.

A five (5) wafer Reactive Ion Etch plasma reactor was used for the following experiments. The wafers rested on the unpowered 12 inch diameter quartz plate which in turn rested on an anodized aluminum electrode.

The counter electrode was stainless steel. The RF frequency was 13.56 MHz. The process conditions for the etching of heavily phosphorus doped polysilicon were as follows:

SiCl₄=200 sccm

Cl₂=20 sccm

Power=200 watts

Temp.=60.degree. C.

Plate Spacing=1 inch

Pressure=20 milliTorr.

The polysilicon etch rate was about 500 angstroms/min. After 50% overetch, the polysilicon was severely undercut, indicating essentially isotropic etching was occurring, additionally, 320 angstroms of gate oxide was lost during the overetch.

The same process as above was used except CH₂Br₂ was added at a flow rate of 20 sccm. The polysilicon etch rate was about 400 angstroms/min. After 50% overetch, SEM pictures indicated the process was highly anisotropic. Vertical wall profiles coincident with the photoresist pattern were obtained. In addition, only 20 angstroms of gate oxide was removed, compared to 320 angstroms for the process without CH₂Br₂.

Dibromomethane is a liquid at room temperature with sufficient vapor pressure to be directly metered by conventional flow devices such as mass flowmeters without pressure regulation, as will be apparent to those skilled in the art.

Thus, when used under the proper conditions, it is apparent that CH₂Br₂ can prevent lateral etching and increase the selectivity to SiO₂. In an analogous reaction to Br₂, the CH₂Br₂ can scavenge free Cl atoms, i.e.
4Cl+CH₂Br₂→2HCl+2Br+CCl₂+ΔG ° C.₂₉₈=−30.8 kcal/mole,

that apparently are the species participating in the lateral etching.

In addition to the prevention of undercutting in any Cl-containing etch, CH₂Br₂ addition can be used in a F-containing plasma. CH₂Br₂ reacts spontaneously with F atoms, i.e.
6F+CH₂Br₂→2HF+2Br+CF₄+ΔG ° C.₂₉₈=−95.8 kcal/mole.

This can be used to advantage to prevent undercutting caused by F atoms. The F/C ratio is an important parameter that can be related to the SiO₂ to silicon etch-rate ratio during SiO₂ etching. Since CH₂Br₂ can scavenge F atoms, it can be used to control the F/C ratio and thus the selectivity during SiO₂ etching.

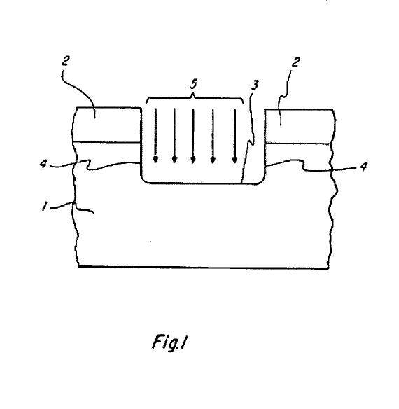

FIG. 1 is a cross-sectional view of the etch process of one embodiment of the present invention. The silicon material 1 is covered by an insulator 2 except in those areas where the surface 3 is to be formed. The ion bombardment 5 of the plasma discharge inhibits the formation of non-volatile compounds on the etch surface 3, but on the sidewalls of the etched cavity the non-volatile compound 4, e.g., a Br—Si compound, forms and adsorbs on the sidewalls.

The results of the tests conducted indicate that the addition of dibromomethane to certain halogen-bearing gases contributes significantly to a nearly perfect vertical etch of silicon. In particular, the combination of SiCl₄, Cl₂ and CH₂Br₂ yields highly desirable results in that the etched surface of the silicon is very smooth. Therefore, the apparent improvements to the plasma etch process, in the form of increased etch rates and nearly perfect vertical etch (substantially no undercutting), without the need for poisonous gasses such as HBr, afforded by the present invention, will be immediately recognized by those skilled in the art.

It should be noted that, while the use of dibromomethane may be crucial in achieving the advantage of the present invention, the use of SiCl₄ and/or Cl₂ is not critical at all. A wide variety of other chlorine-bearing etchants such as carbon tetrachloride, phosphorus trichloride, chlorine, hydrogen chloride, boron trichloride, molecular chlorine, and combinations thereof can be substituted for the SiCl₄ and/or Cl₂. Moreover, a fluorine-bearing gas such as tetrafluoromethane, hexafluoromethane, octofluoropentane, sulfur hexafluoride, and combinations thereof, or a fluorine and chlorine-bearing species such as trifluoromethane, trifluorochloromethane, difluorodichloromethane, fluorotrichloromethane, and combinations thereof can also alternatively be used as the etchant gas. Thus, for example, use of dibromomethane in combination with such etchant gas species as tetrafluoromethane, hexafluoromethane, octofluoropentane, trifluoromethane, trifluorochloromethane, difluorodichloromethane, fluorotrichloromethane, or a wide variety of others are in the scope of the present invention.

To the dibromomethane bearing etchant gas, oxygen, nitrogen and/or, inert gases such as helium, neon, argon, krypton, and xenon can be added to the mixture.

Since the crucial advantage of the present invention may be derived in large part from the function of dibromomethane as a safe and environmentally friendly source for a sidewall passivation agent, the etch process taught by an embodiment of the present invention is applicable not only to single crystalline silicon or polysilicon, but is also applicable to other compositions which contain a large silicon content, for example, tungsten silicide and silicon carbide which are as much as one half silicon by atomic composition. Thus, the etch mixture taught by an embodiment of the present invention is not only applicable to anisotropic etching of silicon nitride, but also is applicable to anisotropic etching of a wide variety of metal silicides. Where the present invention is applied to etching silicides, the etchant gas is preferably a gas containing both chlorine and fluorine-bearing species, to accomplish transport of the metal away from the etch site. However, a mixture of dibromomethane with an etchant gas containing only chlorine-bearing species, or only fluorine-bearing species, is alternatively possible.

In the above example as applied to anisotropic etching of polysilicon, there is used a pressure of about 20 milliTorr, RF power of about 200 watts, a silicon tetrachloride flow rate of about 200 sccm, a chlorine flow rate of about 10 sccm, and a dibromomethane flow rate of about 10 sccm. However, polysilicon etching may be practiced with a broad range of substitutions in this preferred formula, including pressure in the range of about 0.005 Torr to about 5.0 Torr, power density in the range of about 1 to about 30 watts per square inch, halogen-bearing gas flow in the range of about 1 to about 1000 sccm, chlorine gas flow rate in the range of 0 to 30 times the flow rate of the other halogen-bearing etchant, and dibromomethane flow rate in the range of about 1% to about 25%, more preferably 9%. The flow rate of the halogen-bearing etchant is based upon the weight ratio of the bromine in the dibromomethane to the halogen or halogens in the etchant chloride and/or fluoride.

Thus, the present invention provides the advantage of an anisotropic etch for silicon.

The present invention provides the further advantage of an anisotropic etch for silicon or polysilicon, which is insensitive to doping level.

The present invention provides the further advantage of a highly anisotropic etch for silicon-bearing materials, which is highly insensitive to doping level.

The present invention provides the further advantage of a highly anisotropic etch for silicon, which leaves a clean etched surface.

The present invention provides the further advantage of a highly selective etch of polysilicon to silicon dioxide, for example, at least about 10:1.

The present invention provides the further advantage of an environmentally friendly etch.

Though the invention has been described with respect to specific preferred embodiments thereof, many variations and modifications will immediately become apparent to those skilled in the art. It is therefore the intention that the appended claims be interpreted as broadly as possible in view of the prior art to include all such variations and modifications.

1. A method for selectively etching a layer of a silicon-bearing material in producing a semiconductor device, the method comprising:
providing a patterned masking material over the silicon-bearing material to expose portions of the silicon-bearing material to be etched; and
passing a gaseous mixture over the layer, wherein the gaseous mixture comprises dibromomethane.

2. The method of claim 1, further comprising:
creating a plasma discharge in the gaseous mixture adjacent to the layer of silicon-bearing material.

3. The method of claim 1, wherein the gaseous mixture further comprises chlorine-bearing species.

4. The method of claim 3, wherein the chlorine-bearing species is selected from the group consisting of: silicon tetrachloride, carbon tetrachloride, phosphorus trichloride, chlorine, hydrogen chloride, and combinations thereof.

5. The method of claim 3, wherein the bromine-chlorine mole ratio is in the range of from about 1% to about 10%.

6. The method of claim 5, wherein the bromine-chlorine mole ratio is about 9%.

7. The method of claim 1, wherein the gaseous mixture further comprises a fluorine-bearing species.

8. The method of claim 7, wherein the fluorine-bearing species is selected from the group consisting of tetrafluoromethane, hexafluoromethane octofluoropentane, sulfur hexafluoride, and combinations thereof.

9. The method of claim 7, wherein the mole ratio of bromine to fluorine is from about 1% to about 10%.

10. The method of claim 9, wherein the mole ratio of bromine to fluorine is about 9%

11. The method of claim 1, wherein the gaseous mixture further comprises a fluorine and chlorine-bearing species.

12. The method of claim 11, wherein the fluorine and chlorine-bearing species comprises a gas selected from the group consisting of: trifluoromethane, trifluorochloromethane, difluorodichloromethane, fluorotrichloromethane, and combinations thereof.

13. The method of claim 11, wherein the mole ratio of bromine to fluorine and chlorine is from about 1% to about 10%.

14. The method of claim 1, wherein the gaseous mixture includes an inert gas.

15. The method of claim 3, wherein the gaseous mixture includes an inert gas.

16. The method of claim 7, wherein the gaseous mixture includes an inert gas.

17. The method of claim 11, wherein the gaseous mixture includes an inert gas.

18. The method of claim 1, wherein the gaseous mixture further comprises a mixture of CF₄ and O₂.

19. A plasma etching gas mixture for selectively etching a layer of a silicon-bearing material in producing a semiconductor device, the gas mixture comprising:
dibromomethane, and at least one of a chlorine-bearing species, fluorine-bearing species and a fluorine and chlorine-bearing species.

20. The mixture of claim 19, wherein the mixture further includes an inert gas.

21. The mixture of claim 19, wherein the chlorine-bearing species is selected from the group consisting of: silicon tetrachloride, carbon tetrachloride, phosphorus trichloride, chlorine, hydrogen chloride, and combinations thereof.

22. The mixture of claim 19, wherein the fluorine-bearing species is selected from the group consisting of tetrafluoromethane, hexafluoromethane octofluoropentane, sulfur hexafluoride, and combinations thereof.

23. The mixture of claim 19, wherein the fluorine and chlorine-bearing species comprises a gas selected from the group consisting of: trifluoromethane, trifluorochloromethane, difluorodichloromethane, fluorotrichloromethane, and combinations thereof.

24. A plasma etching gas mixture for selectively etching a layer of a silicon-bearing material in producing a semiconductor device, the gas mixture comprising:
dibromomethane; at least one of a chlorine-bearing species, fluorine-bearing species, and a fluorine and chlorine-bearing species; and an inert gas,
wherein the etching gas mixture comprises 1% to 10% dibromomethane.
